(19) United States
(12) Patent Application Publication
(10) Pub. No.: US 2021/0005770 A1
(43) Pub. Date: Jan. 7, 2021

(54) LIGHTING DEVICE

(71) Applicants: Chengdu BOE Optoelectronics Technology Co., Ltd., Sichuan (CN); BOE TECHNOLOGY GROUP CO., LTD., Beijing (CN)

(72) Inventors: Biao XU, Beijing (CN); Lin ZHANG, Beijing (CN)

(21) Appl. No.: 16/794,518

(22) Filed: Feb. 19, 2020

(30) Foreign Application Priority Data
Jul. 3, 2019 (CN) 201910595870.0

(51) Int. Cl. H01L 31/12; H01L 31/0216; H01L 27/32; H01L 51/00; H01L 51/50

(52) U.S. Cl. CPC H01L 31/125; H01L 31/02162; H01L 51/5036; H01L 51/0097; H01L 27/3227

(57) ABSTRACT

This disclosure provides a lighting device, which relates to a field of display technologies. The lighting device of the present disclosure includes: a light emitting panel emitting a predetermined color light; and a solar cell panel disposed on a light-emitting side of the light emitting panel and including an active layer. The active layer has no absorption within a wavelength range of the predetermined color light. The lighting device can ensure to be self-powered under normal light emission when the solar cell panel is disposed on the light-emitting side of the light emitting panel.

### CROSS-REFERENCE TO RELATED APPLICATIONS

This application is based on and claims priority to the Chinese application No. 201910595870.0, filed on Jul. 3, 2019, the entire contents of which are incorporated herein by reference.

### TECHNICAL FIELD

The present disclosure relates to the field of display technologies, and in particular, to a lighting device.

### BACKGROUND

In the prior art, a solar cell panel is disposed on a light-emitting side of the light emitting panel. However, either light emitted from the light emitting panel is absorbed by the solar light emitting panel to cause the lighting device can not normally emit light, or the solar cell panel does not absorb visible light in order not to impede the display performance of the light emitting panel, in this case, the light absorbed by the solar light emitting panel can be very little, and efficiency of converting optical energy into electric energy is extremely low, and the solar cell panel under such circumstance cannot make the lighting device self-powered, and there isn't a solar cell panel that does completely not absorb visible light. Thus, it is currently impossible to dispose the solar cell panel on the light-emitting side of the light emitting panel.

Therefore, when the solar cell panel is disposed on the light-emitting side of the light emitting panel, an urgent problem is how to ensure the lighting device to be self-powered under the condition that the lighting device normally emits light.

### SUMMARY

An embodiment of the present disclosure provides a lighting device. A main objective of the present application is to ensure the lighting device supplies power by itself under normal light emission when the solar cell panel is disposed on a light-emitting side of a light emitting panel.

In order to achieve the above objective, the present disclosure mainly provides technical solutions below.

On the first aspect, an embodiment of the present disclosure provides a lighting device including a light emitting panel and a solar cell panel. The light emitting panel emits a predetermined color light. The solar cell panel is disposed on a light-emitting side of the light emitting panel and has an active layer. The active layer has no absorption within a wavelength range of the predetermined color light.

In one embodiment, the active layer has absorption within a wavelength range of an ultraviolet light.

In one embodiment, the predetermined color light is a red light with a wavelength range of 600 nm-720 nm, and the active layer has no absorption within the wavelength range of 600 nm-720 nm.

In one embodiment, the predetermined color light is a green light with a wavelength range of 500 nm-570 nm, and the active layer has no absorption within the wavelength range of 500 nm-570 nm.

In one embodiment, the predetermined color light is a blue light with a wavelength range of 450 nm-500 nm, and the active layer has no absorption within the wavelength range of 450 nm-500 nm.

In one embodiment, the active layer comprises a donor material and an acceptor material for absorbing light.

In one embodiment, the solar cell panel is adhered to the light emitting panel through an adhesive layer.

In one embodiment, the solar cell panel is a semitransparent flexible structure.

In one embodiment, the light emitting panel is an opaque flexible light emitting panel.

In one embodiment, the solar cell panel is composed of a first substrate layer, a first anode layer, an active layer, a void transport layer, an electron transport layer, a first cathode layer, and a first packaging layer. The light emitting panel is composed of a second substrate layer, a circuit layer, a second anode layer, a second organic layer, a second cathode layer, and a second packaging layer.

The lighting device according to the embodiment of the present disclosure includes a light emitting panel and a solar cell panel. The solar cell panel is disposed on a light-emitting side of the light emitting panel, and the light emitting panel emits a predetermined color light. When the light emitting panel emits the predetermined color light, since the predetermined color light can pass through the solar cell panel, in which the active layer is included has no absorption within the wavelength range of the predetermined color light, the predetermined color light would not be absorbed when passing through the solar cell panel, and would be normally emitted, such that the lighting device can emit light normally, and, the active layer can absorb light with other wavelengths and convert the optical energy into the electric energy, so that the solar cell panel can absorb light that can be absorbed by the active layer except for the predetermined color light. The solar cell panel and the light emitting panel are connected through an external circuit, and the solar cell panel transmits electric energy to the light emitting panel, such that the solar cell panel can supply power to the light emitting panel. The light emitting panel emits the predetermined color light via the electric energy transmitted by the solar cell panel, so that the lighting device can be self-powered. Therefore, in the lighting device provided by the present disclosure, when the solar cell panel is disposed on the light-emitting side of the light emitting panel, the active layer included in the solar cell panel has no absorption to the predetermined color light emitted from the light emitting panel, such that the lighting device can emit light normally and also can be self-powered.

The above description is only an overview of the technical solution of the present disclosure. In order to understand the technical means of the present disclosure more clearly, it can be implemented according to contents of the description, and in order to make the above and other objects, features, and advantages of the present disclosure more comprehensible, specific embodiments of the present disclosure below are enumerated.

### BRIEF DESCRIPTION OF THE DRAWINGS

FIG. 1 is a schematic structural view of a lighting device according to an embodiment of the present disclosure.

FIG. 2 is a schematic structural view of another lighting device according to an embodiment of the present disclosure.

FIG. 3 is a working principle diagram of a red-light lighting device according to an embodiment of the present disclosure.

FIG. 4 is a working principle diagram of a green-light lighting device according to an embodiment of the present disclosure.

FIG. 5 is a working principle diagram of a blue-light lighting device according to an embodiment of the present disclosure.

FIG. 6 is an absorption diagram of a donor material and acceptor material system (P3HT: PCBM) of an active layer in a solar cell panel according to an embodiment of the present disclosure.

### DETAILED DESCRIPTION

In order to further explain technical means and effects adopted by the present disclosure to achieve the intended purpose of the present disclosure, specific implementations, structures, characteristics, and effects of the lighting device according to the present disclosure will be described in detail below with reference to the accompanying drawings and preferred embodiments.

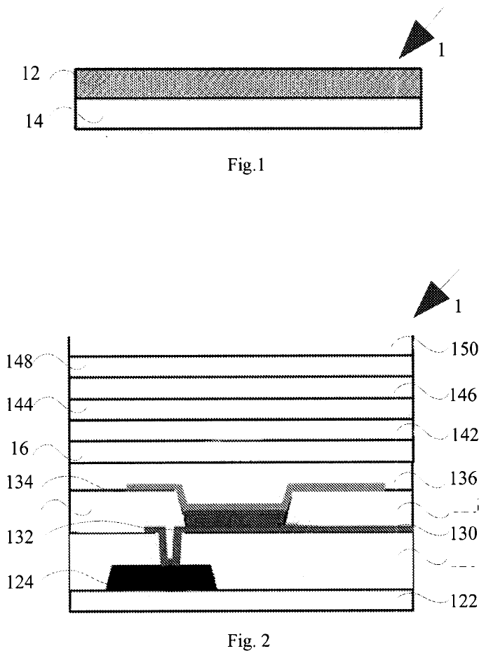

As shown in FIG. 1 to FIG. 6, an embodiment of the present disclosure provides a lighting device, including:

a light emitting panel 12 emitting a predetermined color light; and

a solar cell panel 14 disposed on a light-emitting side of the light emitting panel 12 and including an active layer that has no absorption within a wavelength range of the predetermined color light.

As shown in FIG. 1, the lighting device 1 according to the embodiment of the present disclosure includes a light emitting panel 12 and a solar cell panel 14. The solar cell panel 14 is disposed on the light-emitting side of the light emitting panel 12, and the light emitting panel 12 emits the predetermined color light. When the light emitting panel 12 emits the predetermined color light, the predetermined color light passes through the solar cell panel 14, and the active layer included in the solar cell panel 14 has no absorption within the wavelength range of the predetermined color light (“no absorption” means that the active layer does not absorb the predetermined color light), so that the predetermined color light would not be absorbed when passing through the solar cell panel 14, and the active layer absorbs light with other wavelengths except for the wavelength range of the predetermined color light and converts the optical energy into the electric energy, and the predetermined color light would be emitted normally, so that the lighting device 1 can emit light normally. The active layer included in the solar cell panel 14 has no absorption within the wavelength range of the predetermined color light, but has absorption within other wavelength ranges (i.e., the active layer can absorb light with other wavelengths), so that the solar cell panel 14 can absorb light that can be absorbed by the active layer expect for the predetermined color light, and thereby meeting requirements of the light emitting panel 12. The solar cell panel 14 is connected to the light emitting panel 12 through an external circuit, and transmits the electric energy to the light emitting panel 12, such that the solar cell panel 14 can supply power to the light emitting panel 12. The light emitting panel 12 emits the predetermined color light via the electric energy transmitted by the solar cell panel 14, such that the lighting device 1 can be self-powered. For the lighting device 1 provided by the present disclosure, when the solar cell panel 14 is disposed on the light-emitting side of the light emitting panel 12, the active layer included in the solar cell panel 14 does not absorb the predetermined color light emitted from the light emitting panel 12, so that the lighting device 1 can emit light normally and also the lighting device 1 can be self-powered.

The present disclosure will be further described in detail below with reference to the accompanying drawings and embodiments.

In the embodiment of the present disclosure, the active layer has absorption within a wavelength range of the ultraviolet light.

In this embodiment, because of long-term exposure to ultraviolet light, aging and damage of the light emitting panel 12 can be accelerated, service life of the light emitting panel 12 can be affected, and display brightness of the light emitting panel 12 can be attenuated. In the lighting device 1 provided by the present disclosure, the solar cell panel 14 is disposed on a light-emitting side of the light emitting panel 12, and the active layer of the solar cell panel 14 has absorption within a wavelength range of ultraviolet light, that is, the active layer of the solar cell panel can absorb the ultraviolet light, such that when the ultraviolet light irradiates onto the lighting device 1, the ultraviolet light irradiates onto the solar cell panel 14 in advance, and the active layer in the solar cell panel 14 has absorption within the wavelength range of the ultraviolet light, so that the ultraviolet light that has irradiated onto the solar cell panel 14 can be absorbed by the active layer in the solar cell panel 14, and thereby cannot irradiate onto the light emitting panel 12 again, to prevent the light emitting panel 12 from being irradiated by the ultraviolet light, and avoid aging, damage and attenuation of light brightness of the light emitting panel 12 due to the ultraviolet light, and thus prolong the service life of the light emitting panel 12. The active layer that has absorbed the light of other wavelength except for the predetermined color light can convert the optical energy of the ultraviolet light into the electric energy, and thereby improving the photoelectric conversion rate.

In an embodiment of the present disclosure, the predetermined color light is a red light with a wavelength range of 600 nm-720 nm, and the active layer has no absorption within the wavelength range of 600 nm-720 nm.

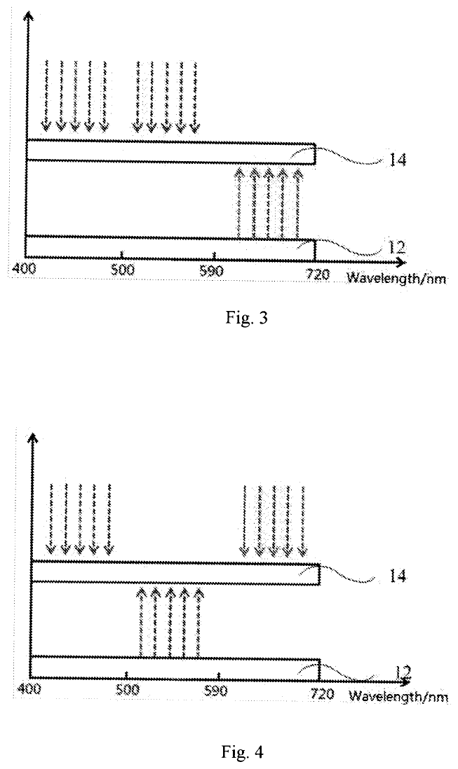

In this embodiment, FIG. 3 is a working principle diagram of the red-light lighting device 1, and an arrow direction in FIG. 3 indicates a propagation direction of the light. In FIG. 3, a light from the light emitting panel 12 to the solar cell panel is a red light, and lights from the outside to the solar cell panel 14 is a green light and a blue light. A horizontal ordinate (X-axis) in the figure indicates a wavelength of light. When the light emitting panel 12 emits the red light, the red light is within a wavelength range of 600 nm-720 nm. The active layer in the solar cell panel 14 has no absorption within the wavelength range of 600 nm-720 nm, so that when the light emitting panel 12 emits red light, the solar cell panel 14 cannot absorb the red light emitted from the light emitting panel 12, and the lighting device 1 can emit red light. The other lights incident on the solar cell panel 14, such as blue light and green light can be absorbed, and then the absorbed blue or green lights can be converted into the electric energy by the solar cell panel 14, and the electric energy can be transmitted to the light emitting panel 12 through an external circuit for red light emission of the lighting emitting panel 12, so that the lighting device 1 can not only emit red light normally, but also realize being self-powered.

In an embodiment of the present disclosure, the predetermined color light is a green light with a wavelength range of 500 nm-570 nm, and the active layer has no absorption within a wavelength range of 500 nm-570 nm.

In this embodiment, FIG. 4 is a working principle diagram of the green-light lighting device 1, and an arrow direction in FIG. 4 indicates a propagation direction of the light. In FIG. 4, the light from the light emitting panel 12 to the solar cell panel is a green light, and the lights from the outside to the solar cell panel 14 are red light and blue light. The horizontal ordinate in the figure indicates the wavelength of the light. When the light emitting panel 12 emits the green light with a wavelength range of 500 nm-570 nm, the active layer in the solar cell panel 14 has no absorption within the wavelength range of 500 nm-570 nm, so that when the light emitting panel 12 emits green light, the solar cell panel 14 cannot absorb the green light emitted from the light emitting panel 12, and the lighting device 1 can emit the green light. The other light incident on the solar cell panel 14, such as the blue light and the red light can be absorbed, and then the absorbed red or blue light can be converted into the electric energy by the solar cell panel 14, and the electric energy can be transmitted to the light emitting panel 12 through an external circuit, for the green light emission of the light emitting panel 12, so that the lighting device 1 can not only emit green light normally, but also realize being self-powered.

In an embodiment of the present disclosure, the predetermined color light is a blue light with a wavelength range of 450 nm-500 nm, and the active layer has no absorption within the wavelength range of 450 nm-500 nm.

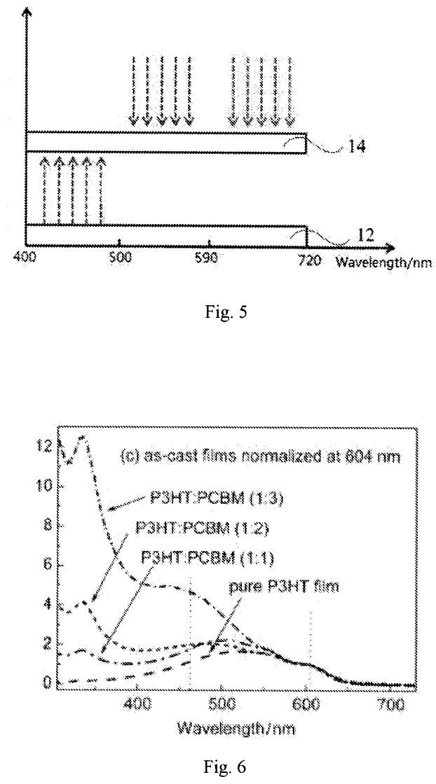

In this embodiment, FIG. 5 is a working principle diagram of the blue-light lighting device 1, and an arrow direction in FIG. 5 indicates the propagation direction of light. In FIG. 5, the light from the light emitting panel 12 to the solar cell panel is a blue light, and the lights from the outside to the solar cell panel 14 are a red light and a green light. The horizontal ordinate in the figure indicates the wavelength of light. When the light emitting panel 12 emits the blue light with a wavelength range of 450 nm-500 nm, the active layer in the solar cell panel 14 has no absorption within the wavelength range of 450 nm-500 nm, so that when the light emitting panel 12 emits blue light, the solar cell panel 14 cannot absorb the blue light emitted from the light emitting panel 12, and the lighting device 1 can emit the blue light. The other lights incident on the solar cell panel 14, such as red light and green light can be absorbed, and then the absorbed red or blue light can be converted into the electric energy by the solar cell panel 14, and the electric energy can be transmitted to the light emitting panel 12 through an external circuit for the blue light emission of the light emitting panel 12, so that the lighting device 1 can not only emit blue light normally, but also realize being self-powered.

In an embodiment of the present disclosure, the active layer includes a donor material and an acceptor material, and the donor material and the acceptor material are used to absorb light.

In this embodiment, the active layer includes a donor material and an acceptor material. The donor material and the acceptor material are used to absorb optical energy and convert the optical energy into electric energy. The active layer has absorption within a wavelength range of the ultraviolet light, that is, the active layer includes the donor material and the acceptor material, which have absorption within the wavelength range of ultraviolet light. The active layer has no absorption within the wavelength range of the predetermined color light, that is, the active layer includes the donor material and the acceptor material, which have no absorption within the wavelength range of the predetermined color light.

As shown in FIG. 6, in an embodiment of the present disclosure, when the light emitted from the light emitting panel 12 is the red light, the active layer includes the donor material and the acceptor material, which have no absorption within a wavelength range of 600 nm to 720 nm. The donor material and the acceptor material can be in a P3HT: PCBM system. The wavelength range absorbed by the P3HT: PCBM system is about 300 nm-600 nm and there is only weak absorption between 600 nm-650 nm. With respect to the red light, a peak emission spectrum is about 640 nm, at this time, the red light emitted from the light emitting panel 12 can pass through the solar cell panel 14 well, and the wavelength range of the ultraviolet light is 300-400 nm, and the P3HT: PCBM material system has great absorption in the ultraviolet light region, to prevent the ultraviolet light from irradiating onto the light emitting panel 12 and prolong the service life of the light emitting panel 12. The donor material and the acceptor material can absorb light of other wavelengths other than the red light, so that the photoelectric conversion rate can be improved.

In an embodiment of the present disclosure, the solar cell panel 14 is adhered to the light emitting panel 12 through an adhesive layer 16.

In an embodiment of the present disclosure, the solar cell panel 14 is composed of a first substrate layer 142, a first anode layer 144, an active layer, a void transport layer, an electron transport layer, a first cathode layer 148, and a first packaging layer 150.

In an embodiment of the present disclosure, the light emitting panel 12 is composed of a second substrate layer 122, a circuit layer, a second anode layer 130, a second organic layer 132, a second cathode layer 134, and a second packaging layer 136.

In this embodiment, as shown in FIG. 2, the solar cell panel 14 is composed of a CPI substrate layer, a first anode layer 144, a first organic layer 146, a first cathode layer 148, and a first packaging layer 150. The first organic layer 146 includes other functional layers such as an active layer, a void transport layer, and an electron transport layer. The light emitting panel 12 is composed of a PI base, a second circuit layer, a second anode layer 130, a second organic layer 132, a second cathode layer 134, and a second packaging layer 136. The circuit layer includes metal traces 124, PDL (pixel definition Layer) 126 and PLN (planarization layer) 128. The solar cell panel 14 and the light emitting panel 12 are bonded by an adhesive layer 16, wherein the adhesive layer may be made of a material such as optical transparent glue.

In an embodiment of the present disclosure, the solar cell panel 14 is a semitransparent flexible structure.

In an embodiment of the present disclosure, the light emitting panel 12 is an opaque flexible light emitting panel 12.

In this embodiment, a process flow for manufacturing a lighting device includes:

Step 101: manufacturing a solar cell panel, wherein a flexible CPI substrate is selected, a first anode layer, a void transport layer, an active layer and an electron transport are sequentially prepared on the flexible CPI substrate from bottom to top, and a first cathode layer is finally prepared, and then being packaged to form a first packaging layer;

Step 102: manufacturing a light emitting panel, wherein a flexible PI substrate is selected, metal traces, a flat layer, a pixel definition layer, a second anode layer and a second organic layer are sequentially prepared on the flexible PI substrate from bottom to top, and a second cathode layer is finally prepared, and then being packaged to form a second packaging layer;

Step 103: bonding the solar cell panel and the light emitting panel through an adhesive layer, wherein the solar cell panel is located at a light-emitting side of the light emitting panel.

In this embodiment, in the manufacturing process of the light emitting panel and the solar cell panel, the manufacturing process of the organic layer can be implemented by inkjet printing or evaporation, the cathode layer and the anode layer can be implemented by evaporation, and the packaging layer uses a flexible TFE structure. Thus, the solar cell panel is a semitransparent flexible structure, and the light emitting panel is an opaque flexible light emitting panel. The solar cell panel with the semitransparent flexible structure will not hinder the light emitted from the light emitting panel, and thereby ensuring the light-emitting effect of the lighting device.

In an embodiment of the present disclosure, the light emitting panel is an OLED light emitting panel.

Optionally, the light emitting panel may also be an LED light emitting panel, a QLED light emitting panel, or a MicroLED light emitting panel.

In an embodiment of the present disclosure, the lighting device is an OLED solar decorative light, and the OLED solar decorative light can be applied to outdoor areas such as car outlines, building outlines, bridges, squares, and playgrounds.

An embodiment of the present disclosure proposes a lighting device, which includes a light emitting panel and a solar cell panel. The solar cell panel is disposed on a light-emitting side of the light emitting panel, and the light emitting panel emits a predetermined color light. When the light emitting panel emits the predetermined color light, the light passes through the solar cell panel. The active layer included in the solar cell panel has no absorption within the wavelength range of the predetermined color light, so that the predetermined color light cannot be absorbed when passing through the solar cell panel, and can be normally emitted, and thus the lighting device can emit light normally. Also, the active layer can absorb light with other wavelengths and convert the optical energy into the electric energy, so that the solar cell panel can absorb light that can be absorbed by the active layer except for the predetermined color light. The solar cell panel and the light emitting panel are connected through an external circuit, and the solar cell panel transmits the electric energy to the light emitting panel, such that the solar cell panel can supply power to the light emitting panel. The light emitting panel emits the predetermined color light via the electric energy transmitted by the solar cell panel, so that the lighting device can be self-powered. Therefore, in the lighting device provided by the present disclosure, when the solar cell panel is disposed on the light-emitting side of the light emitting panel, the active layer included in the solar cell panel has no absorption to the predetermined color light emitted from the light emitting panel, such that the lighting device can emit light normally and also can be self-powered.

The present disclosure is described merely through aforesaid specific implementations, but the protection scope of the present disclosure is not limited thereto. Any person skilled in the art may easily think of variations or substitutions within the technical scope as disclosed in the present disclosure, which all should be contained within the scope of the disclosure. Therefore, the protection scope of the present disclosure should be determined depending on the protection scope of the claims.

What is claimed is:

1. A lighting device comprising:
a light emitting panel emitting a predetermined color light; and
a solar cell panel disposed on a light-emitting side of the light emitting panel and comprising an active layer, the active layer having no absorption within a wavelength range of the predetermined color light.

2. The lighting device according to claim 1, wherein the active layer has absorption within a wavelength range of an ultraviolet light.

3. The lighting device according to claim 2, wherein the predetermined color light is a red light with a wavelength range of 600 nm-720 nm, and the active layer has no absorption within the wavelength range of 600 nm-720 nm.

4. The lighting device according to claim 2, wherein the predetermined color light is a green light with a wavelength range of 500 nm-570 nm, and the active layer has no absorption within the wavelength range of 500 nm-570 nm.

5. The lighting device according to claim 2, wherein the predetermined color light is a blue light with a wavelength range of 450 nm-500 nm, and the active layer has no absorption within the wavelength range of 450 nm-500 nm.

6. The lighting device according to claim 1, wherein the active layer comprises a donor material and an acceptor material for absorbing light.

7. The lighting device according to claim 1, wherein the solar cell panel is adhered to the light emitting panel through an adhesive layer.

8. The lighting device according to claim 1, wherein the solar cell panel is a semitransparent flexible structure.

9. The lighting device according to claim 1, wherein the light emitting panel is an opaque flexible light emitting panel.

10. The lighting device according to claim 1, wherein the solar cell panel is composed of a first substrate layer, a first anode layer, an active layer, a void transport layer, an electron transport layer, a first cathode layer, and a first packaging layer; and
the light emitting panel is composed of a second substrate layer, a circuit layer, a second anode layer, a second organic layer, a second cathode layer, and a second packaging layer.
